(19) United States
(12) Patent Application Publication
(10) Pub. No.: US 2014/0094024 A1
(43) Pub. Date: Apr. 3, 2014

(54) PLASMA DOPING APPARATUS, PLASMA DOPING METHOD, AND METHOD FOR MANUFACTURING SEMICONDUCTOR DEVICE

(71) Applicant: TOKYO ELECTRON LIMITED, Tokyo (JP)

(72) Inventors: Masahiro OKA, Miyagi (JP); Yuuki KOBAYASHI, Miyagi (JP); Hirokazu UEDA, Miyagi (JP); Masahiro HORIGOME, Miyagi (JP)

(73) Assignee: TOKYO ELECTRON LIMITED, Tokyo (JP)

(21) Appl. No.: 14/039,761

(22) Filed: Sep. 27, 2013

(30) Foreign Application Priority Data
Oct. 2, 2012 (JP) 2012-220101

(51) Int. Cl. H01L 21/22; H01L 21/67

(52) U.S. Cl. CPC H01L 21/22; H01L 21/67011
USPC 438/513; 118/696

(57) ABSTRACT

Disclosed is a plasma doping apparatus including a processing chamber, a substrate holding unit, a plasma generating mechanism, a pressure control mechanism, a bias power supply mechanism, and a control unit. The control unit controls the pressure within the processing chamber to be a first pressure and controls the bias power to be supplied to the holding unit is to be a first bias power for a first plasma process. The control unit also controls the pressure within the processing chamber to be a second pressure which is higher than the first pressure, and controls the bias power to be supplied to the holding unit to be a second bias power which is lower than the first bias power for a second plasma process.

### CROSS-REFERENCE TO RELATED APPLICATIONS

This application is based on and claims priority from Japanese Patent Application No. 2012-220101, filed on Oct. 2, 2012, with the Japan Patent Office, the disclosure of which is incorporated herein in its entirety by reference.

### TECHNICAL FIELD

The present disclosure relates to a plasma doping apparatus, a plasma doping method, and a method for manufacturing a semiconductor device.

### BACKGROUND

Semiconductor devices such as, for example, large scale integrated circuits (LSIs) or metal oxide semiconductor (MOS) transistors have been manufactured by performing various processes such as, for example, a doping, an etching, a chemical vapor deposition (CVD), or a sputtering on a semiconductor substrate (wafer) as a substrate to be processed.

A technology for implanting a dopant into a substrate is disclosed in Japanese Patent Laid-Open Publication No. 2010-519735 in which doping is performed by controlling the pressure within a processing chamber to be within a range from 10 mTorr to 95 mTorr.

### SUMMARY

The present disclosure provides a plasma doping apparatus for performing doping by implanting a dopant into a substrate to be processed. The plasma doping apparatus includes: a processing chamber configured to implant a dopant into a substrate to be processed within the processing chamber; a gas supply unit configured to supply a doping gas and an inert gas for plasma excitation into the processing chamber; a holding unit disposed within the processing chamber and configured to hold the substrate thereon; a plasma generating mechanism configured to generate a plasma within the processing chamber by using a microwave; a pressure control mechanism configured to control a pressure within the processing chamber; a bias power supply mechanism configured to supply an AC bias power to the holding unit; and a control unit configured to control the plasma doping apparatus. The control unit controls the pressure control mechanism such that the pressure within the processing chamber is to be a first pressure and controls the bias power supply mechanism such that the bias power to be supplied to the holding unit is to be a first bias power. Then, a first plasma processing is performed on the substrate by the plasma generated by the plasma generating mechanism. After the first plasma processing, the control unit controls the pressure control mechanism so as to set the pressure within the processing chamber is to be a second pressure which is higher than the first pressure, and controls the bias power supply mechanism such that the bias power to be supplied to the holding unit is to be a second bias power which is lower than the first bias power. Then, a second plasma processing is performed on the substrate by the plasma generated by the plasma generating mechanism.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic perspective view illustrating a part of a FinFET-type semiconductor device which is a semiconductor device manufactured by a plasma doping method and a plasma doping apparatus according to an exemplary embodiment of the present disclosure.

FIG. 2 is a schematic sectional view illustrating a main part of the plasma doping apparatus according to an exemplary embodiment of the present disclosure.

FIG. 3 is a schematic view illustrating a slot antenna plate included in the plasma doping apparatus illustrated in FIG. 2 when viewed in the direction of arrow III in FIG. 2.

FIG. 4 is a flow chart illustrating a schematic process of the plasma doping method according to an exemplary embodiment of the present disclosure.

FIG. 5 is a graph illustrating dopant concentrations at respective measurement positions of a FinFET-type semiconductor device when doping is performed through various methods.

FIG. 6 is an enlarged electron microscopic photograph illustrating a part of a section of a FinFET-type semiconductor device.

FIG. 7 is a sectional view schematically illustrating a part of a section of a FinFET-type semiconductor device when a first plasma process is performed.

FIG. 8 is a sectional view schematically illustrating a part of a section of a FinFET-type semiconductor device when a second plasma process is performed.

FIG. 9 illustrates enlarged electron microscopic photographs illustrating a part of a section of a FinFET-type semiconductor device when doping is performed by the plasma doping method and the plasma doping apparatus according to an exemplary embodiment of the present disclosure. The left photograph illustrates a case before doping, and the right photograph illustrates a case after doping.

FIG. 10 is an enlarged view illustrating a part of a top portion and a side portion of a fin, including a corner portion, in the right photograph of FIG. 9.

FIG. 11 is an enlarged electron microscopic photograph illustrating a part of a section of a FinFET-type semiconductor device when doping is performed by a conventional ion implantation device. The left photograph illustrates a case before doping, and the right photograph illustrates a case after doping.

FIG. 12 is an enlarged view illustrating a top portion and a side portion of a fin, including a corner portion, in the right photograph of FIG. 11.

FIG. 13 is a graph illustrating dopant concentrations at respective measurement positions of a FinFET-type semiconductor device before and after cleaning is performed using DHF (diluted hydrofluoric acid) on a to-be-processed substrate which is doped by the plasma doping method and the plasma doping apparatus according to an exemplary embodiment of the present disclosure.

### DETAILED DESCRIPTION

In the following detailed description, reference is made to the accompanying drawings which form a part of the present application. The illustrative embodiments described in the detailed description, drawings, and claims are not meant to be limiting. Other embodiments may be utilized, and other changes may be made without departing from the spirit or scope of the subject matter presented here.

In a case where doping is performed on a doping target such as a FinFET (Fin Field Effect Transistor) type semiconductor device having a three-dimensional structure (3D structure), a high coatability, that is, a high conformality (uniformity) in doping is required so as to uniformize doping depths from surfaces or dopant concentrations at respective places on the doping target. Specifically, in a shape of a fin which extends upwardly from the main surface of a silicon substrate, it is required that a concentration and doping depth of a dopant implanted from a peak (top) position become equal to a concentration and doping depth of the dopant implanted from a lateral (side) position, respectively, if possible. Of course, even on a side portion of the fin, it is required that the dopant concentrations and doping depths become equal to each other between an area close to the top portion and an area close to a bottom portion (lower portion) formed between adjacent fins, if possible.

In this case, when doping is performed, it is not desirable that the shape is significantly changed after doping as compared to the shape before doping due to the occurrence of, for example, erosion. Further, after the doping process, cleaning, such as, for example, a wet cleaning, is performed using a chemical liquid on the doped substrate. In the cleaning process, it is preferable that the dopant implanted through the doping is not desorbed by, for example, elution.

An aspect of the present disclosure is to provide a plasma doping apparatus comprising: a processing chamber configured to accommodate a substrate to be processed so that the substrate is implanted with a dopant; a gas supply unit configured to supply a doping gas and an inert gas for plasma excitation into the processing chamber; a holding unit disposed within the processing chamber and configured to hold the substrate thereon; a plasma generating mechanism configured to generate a plasma within the processing chamber by using a microwave; a pressure control mechanism configured to control a pressure within the processing chamber; a bias power supply mechanism configured to supply an AC bias power to the holding unit; and a control unit configured to control the plasma doping apparatus. The control unit controls the pressure control mechanism so as to set the pressure within the processing chamber to be a first pressure, and controls the bias power supply mechanism so as to set the bias power to be supplied to the holding unit to be a first bias power, so that a first plasma processing is performed on the substrate by the plasma generated by the plasma generating mechanism, and after the first plasma processing, the control unit controls the pressure control mechanism so as to set the pressure within the processing chamber to be a second pressure which is higher than the first pressure, and controls the bias power supply mechanism so as to set the bias power to be supplied to the holding unit to be a second bias power which is lower than the first bias power, so that a second plasma processing is performed on the substrate by the plasma generated by the plasma generating mechanism.

In such a configuration, in the plasma doping, the pressure control mechanism is controlled such that the pressure within the processing chamber becomes the first pressure, and the bias power supply mechanism is controlled such that the bias power to be supplied to the holding unit becomes the first bias power. Then, the first plasma processing is performed on the substrate by the plasma generated by the plasma generating mechanism. After the first plasma processing, the pressure control mechanism is controlled such that the pressure within the processing chamber becomes the second pressure which is higher than the first pressure, and the bias power supply mechanism is controlled such that the bias power to be supplied to the holding unit becomes the second bias power which is lower than the first bias power. Then, the second plasma processing is performed on the substrate by the plasma generated by the plasma generating mechanism. Thus, it is possible to perform plasma doping without causing a significant change in shape after doping as compared to that before doping while achieving a good conformality. Also, in the following cleaning process, the dopant implanted by doping is hardly desorbed.

The control unit may control the pressure control mechanism such that the second pressure is to be 100 mTorr or more and 250 mTorr or less.

The control unit may control the pressure control mechanism such that the first pressure is to be 5 mTorr or more and less than 100 mTorr.

The control unit may control the bias power supply mechanism such that the second bias power is to be 450 W or more and less than 750 W.

The control unit may control the bias power supply mechanism such that the first bias power is to be 750 W or more and 1100 W or less.

The plasma generating mechanism includes: a microwave generator configured to generate a microwave for plasma excitation; a dielectric window configured to transmit the microwave generated by the microwave generator into the processing chamber, and a slot antenna plate formed with a plurality of slot holes and configured to radiate the microwave to the dielectric window.

The plasma generated by the plasma generating mechanism may be generated through a radial line slot antenna.

Another aspect of the present disclosure is to provide a plasma doping method. The method includes: conducting a first plasma process wherein a substrate to be processed is held on a holding unit disposed within a processing chamber, a pressure within the processing chamber is controlled to be a first pressure, a bias power to be supplied to the holding unit is controlled to be a first bias power, and a plasma is generated within the processing chamber by using a microwave while introducing a doping gas to the processing chamber, thereby implanting a dopant to the substrate; and after the first plasma process, conducting a second plasma process wherein the pressure within the processing chamber is controlled to be a second pressure higher than the first pressure, the bias power to be supplied to the holding unit is controlled to be a second bias power lower than the first bias power, and the plasma is generated within the processing chamber by using a microwave while introducing the doping gas to the processing chamber, thereby implanting the dopant to the substrate.

The second plasma process may be performed in a state where the second pressure is controlled to be 100 mTorr or more and 250 mTorr or less.

The first plasma process may be performed in a state where the first pressure may is controlled to be 5 mTorr or more and less than 100 mTorr.

The second plasma process may be performed in a state where the second bias power is controlled to be 450 W or more and less than 750 W.

The first plasma process may be performed in a state where the first bias power is controlled to be 750 W or more and 1100 W or less.

The plasma generated by using the microwave may be generated through a radial line slot antenna.

A further aspect of the present disclosure is to provide a method of manufacturing a semiconductor device. The method includes: conducting a first plasma process wherein a substrate to be processed is held on a holding unit disposed within a processing chamber, a pressure within the processing chamber is controlled to be a first pressure, a bias power to be supplied to the holding unit is controlled to be a first bias power, and a plasma is generated within the processing chamber by using a microwave while introducing a doping gas to the processing chamber, thereby implanting a dopant to the substrate; and after the first plasma process, conducting a second plasma process wherein the pressure within the processing chamber is controlled to be a second pressure higher than the first pressure, the bias power to be supplied to the holding unit is controlled to be a second bias power lower than the first bias power, and the plasma is generated within the processing chamber by using a microwave while introducing the doping gas to the processing chamber, thereby implanting the dopant to the substrate.

The second plasma process is performed in a state where the second pressure is controlled to be 100 mTorr or more and 250 mTorr or less.

The first plasma process is performed in a state where the first pressure is controlled to be 5 mTorr or more and less than 100 mTorr.

The second plasma process is performed in a state where the second bias power is controlled to be 450 W or more and less than 750 W.

The first plasma process is performed in a state where the first bias power is controlled to be 750 W or more and 1100 W or less.

The plasma generated by using the microwave is generated through a radial line slot antenna.

According to such a configuration, plasma doping may be performed without causing a significant change in shape after doping as compared to that before doping while achieving a good conformality. Also, in the following cleaning process, the dopant implanted through the doping is hardly desorbed.

Hereinafter, exemplary embodiments of the present disclosure will be described with reference to drawings. First, the configuration of a semiconductor device manufactured by a plasma doping method and a plasma doping apparatus according to an exemplary embodiment of the present disclosure will be described.

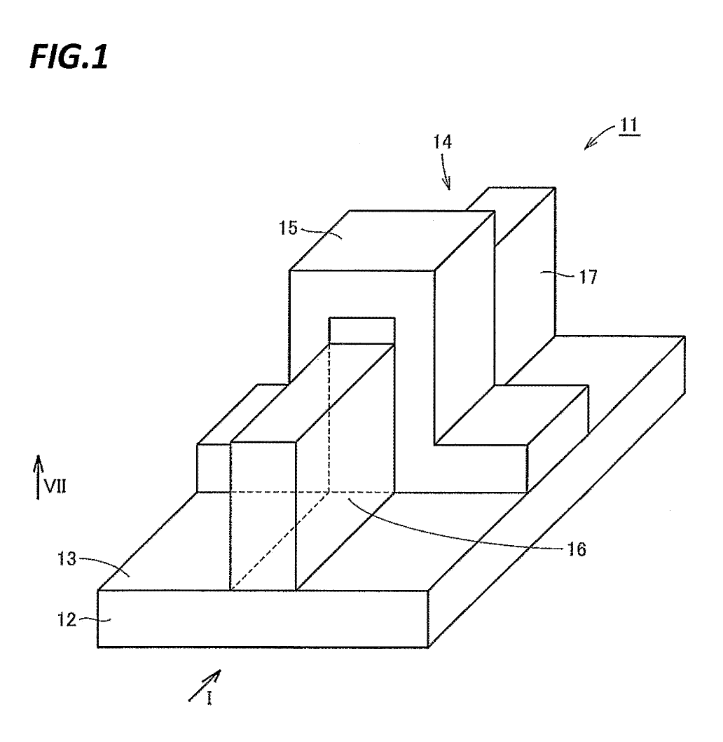

FIG. 1 is a schematic perspective view illustrating a part of a FinFET-type semiconductor device which is a semiconductor device manufactured by a plasma doping method and a plasma doping apparatus according to an exemplary embodiment of the present disclosure. Referring to FIG. 1, a FinFET-type semiconductor device 11, which is manufactured by the plasma doping method and the plasma doping apparatus according to an exemplary embodiment of the present disclosure, is formed with a fin 14 that extends upwardly by a predetermined length from a main surface 13 of a silicon substrate 12. The extension direction of the fin 14 is a direction indicated by arrow I in FIG. 1. The portion of the fin 14 is substantially rectangular when viewed from the direction of the arrow I which is the horizontal direction of the FinFET-type semiconductor device 11. A gate 15 that extends in a direction perpendicular to the extension direction of the fin 14 is formed to cover a part of the fin 14. A source 16 is formed at the front side of the formed gate 15 in the fin 14, and a drain 17 is formed at the rear side. Doping is performed by plasma generated using microwave on such a shape of the fin 14, that is, the surface of a portion extending upwardly from the main surface 13 of the silicon substrate 12.

Also, although not illustrated in FIG. 1, in some semiconductor device manufacturing processes, photoresist layers may be formed in the step before the plasma doping is performed. The photoresist layers are formed at a predetermined interval at the lateral sides of the fin 14, for example, at portions located at the left and right sides of the drawing in FIG. 1. The photoresist layers extend in the same direction as the fin 14 and are formed to protrude upwardly by a predetermined length from the main surface 13 of the silicon substrate 12.

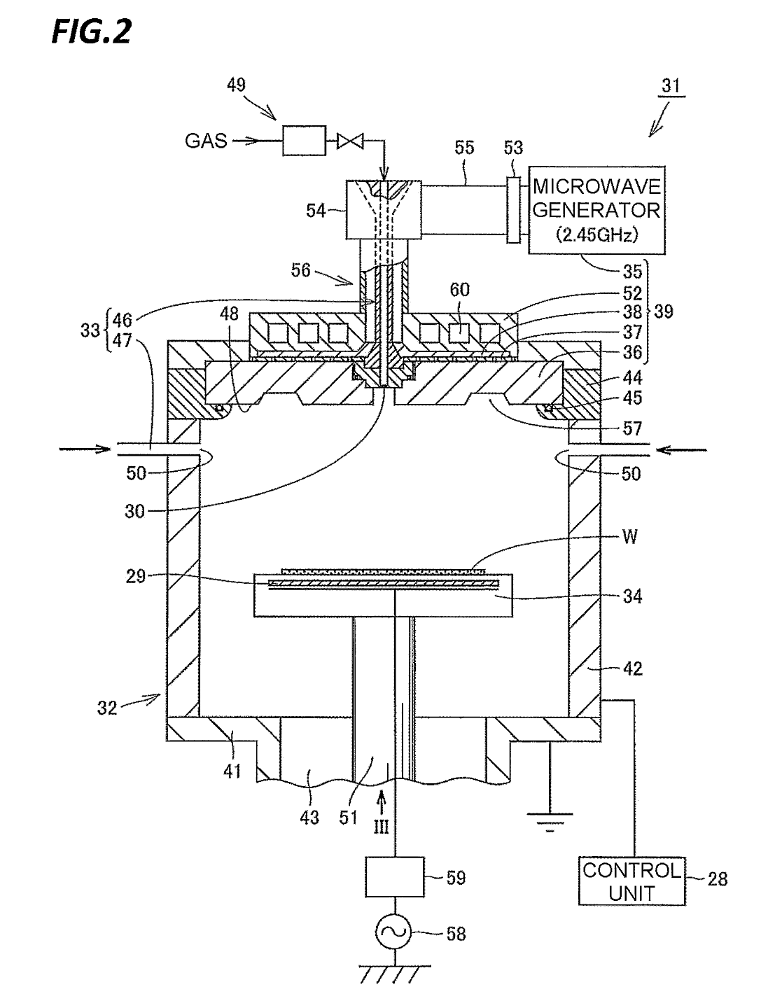

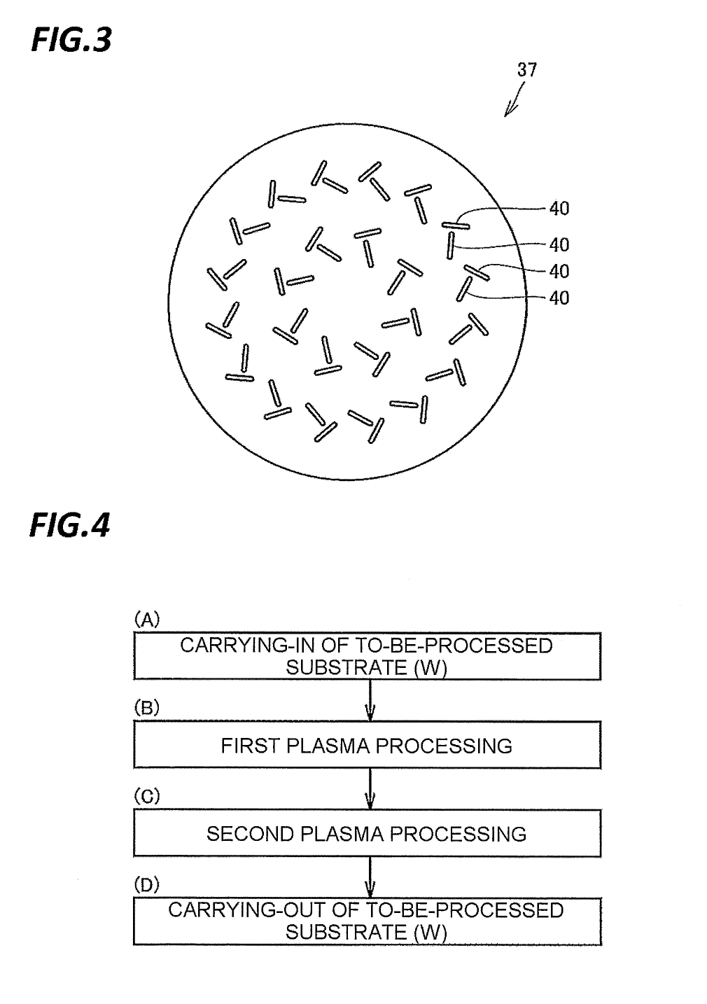

FIG. 2 is a schematic sectional view illustrating a main part of the plasma doping apparatus according to an exemplary embodiment of the present disclosure. Also, FIG. 3 is a view illustrating a slot antenna plate included in the plasma doping apparatus illustrated in FIG. 2 when viewed from the bottom side, that is, the direction of arrow III in FIG. 2. Also, in FIG. 2, hatching of some members is omitted for an easy understanding. Also, in this exemplary embodiment, in FIG. 2, the vertical direction of the drawing is considered as the vertical direction of the plasma doping apparatus.

Referring to FIGS. 2 and 3, a plasma doping apparatus 31 includes a processing chamber 32 configured to perform plasma doping on a substrate W therewithin, a gas supply unit 33 configured to supply a gas for plasma excitation or a doping gas into the processing chamber 32, a disk-shaped holding unit 34 configured to hold the substrate W thereon, a plasma generating mechanism 39 configured to generate plasma within the processing chamber 32 by using microwave, a pressure control mechanism configured to control the pressure within the processing chamber 32, a bias power supply mechanism configured to supply an AC bias power to the holding unit 34, and a control unit 28 configured to control the entire operation of the plasma doping apparatus 31. The control unit 28 serves to control the entire plasma doping apparatus 31, for example, controlling of a gas flow rate in the gas supply unit 33, a pressure within the processing chamber 32, and a bias power to be supplied to the holding unit 34.

The processing chamber 32 includes a bottom portion 41 positioned below the holding unit 34, and a side wall 42 extending upwardly from the outer circumference of the bottom portion 41. The side wall 42 has a substantially cylindrical shape. An exhausting hole 43 for exhausting a gas is formed at the bottom portion 41 of the processing chamber 32 to penetrate a part of the bottom portion 41. The top side of the processing chamber 32 is opened, and the processing chamber 32 is configured to be sealed by a cover part 44 disposed at the top portion of the processing chamber 32, a dielectric window 36 to be described later, and an 0 ring 45 as a sealing member interposed between the dielectric window 36 and the cover part 44.

The gas supply unit 33 includes a first gas supply unit 46 configured to eject a gas toward the center of the substrate W, and a second gas supply unit 47 configured to eject a gas from the outside of the substrate W. A gas supply hole 30 configured to supply the gas from the first gas supply unit 46 is formed at the center of the dielectric window 36 in a diametrical direction, that is, a position retracted inwardly into the dielectric window 36 from the bottom surface 48 of the dielectric window 36. Here, the bottom surface 48 faces the holding unit 34. The first gas supply unit 46 supplies an inert gas for plasma excitation or a doping gas while controlling, for example, a flow rate, via a gas supply system 49 connected to the first gas supply unit 46. The second gas supply unit 47 is formed by forming a plurality of gas supply holes 50 at a part of the upper portion of the side wall 42. The plurality of gas supply holes 50 are configured to supply an inert gas for plasma excitation or a doping gas into the processing chamber 32. The plurality of gas supply holes 50 are formed at equal intervals in the circumferential direction. The first gas supply unit 46 and the second gas supply unit 47 are supplied with the same kind of inert gas for plasma excitation or doping gas from the common gas supply source. Also, according to a demand or control contents, different gases may be supplied from the first gas supply unit 46 and the second gas supply unit 47, and, for example, the flow rate ratio thereof may be adjusted.

In the holding unit 34, a high frequency power source 58 for RF (radio frequency) bias is electrically connected to an electrode within the holding unit 34 via a matching unit 59. The high frequency power source 58 is capable of outputting a predetermined power (bias power) of high frequency of, for example, 13.56 MHz. The matching unit 59 contains a matching device configured to match the impedance at the high frequency power source 58 side with the impedance at the load side mainly such as, for example, the electrode, the plasma, and the processing chamber 32, and a blocking condenser for generating self bias is included in the matching device. Also, at the time of plasma doping, the supply of a bias voltage to the holding unit 34 is appropriately varied if necessary. For the bias power supply mechanism, the control unit 28 controls the AC bias power to be supplied to the holding unit 34.

The holding unit 34 may hold the substrate W thereon by an electrostatic chuck (not illustrated). Also, the holding unit 34 may be provided with, for example, a heater (not illustrated) for heating, and a required temperature may be set by a temperature control mechanism 29 provided within the holding unit 34. The holding unit 34 is supported by an insulative cylindrical support 51 that extends perpendicularly upwardly from the lower side of the bottom portion 41. The exhausting hole 43 is formed to penetrate a part of the bottom portion 41 of the processing chamber 32 along the outer circumference of the cylindrical support 51. An exhaust device (not illustrated) is connected at the lower side of the exhausting hole 43 formed in a ring via an exhaust tube (not illustrated). The exhaust device includes a vacuum pump such as, for example, a turbo molecular pump. The inside of the processing chamber 32 may be depressed to a predetermined pressure by the exhaust device. The control unit 28 is a pressure control mechanism and controls the pressure within the processing chamber 32 through, for example, the control of exhaustion by the exhaust device.

The plasma generating mechanism 39 includes a microwave generator 35 which is provided outside of the processing chamber 32 and configured to generate microwave for plasma excitation. Also, the plasma generating mechanism 39 includes the dielectric window 36 which is disposed at a position facing the holding unit 34, and introduces the microwave generated by the microwave generator 35 into the processing chamber 32. Also, the plasma generating mechanism 39 includes a slot antenna plate 37 which is formed with a plurality of slot holes 40, disposed at the top side of the dielectric window 36, and radiates the microwave to the dielectric window 36. Also, the plasma generating mechanism 39 includes a dielectric member 38 which is disposed on the top of the slot antenna plate 37 and radially propagates the microwave introduced from a coaxial waveguide 56 to be described later.

The microwave generator 35 having a matching 53 is connected to the top of the coaxial waveguide 56 configured to introduce the microwave, via a mode converter 54 and a waveguide 55. For example, a TE-mode microwave generated by the microwave generator 35 passes through the waveguide 55, is converted into a TEM-mode microwave by the mode converter 54, and propagates through the coaxial waveguide 56. As the frequency of the microwave generated by the microwave generator 35, for example, 2.45 GHz is selected.

The dielectric window 36 has a substantially disk shape and is formed of a dielectric. A ring-shaped recess 57, which is recessed in a tapered shape, is provided at a part of the bottom surface 48 of the dielectric window 36, so as to ensure that a standing wave may be easily generated by the introduced microwave. By the recess 57, the plasma may be efficiently generated by the microwave at the bottom side of the dielectric window 36. A specific material for the dielectric window 36 may be, for example, quartz or alumina.

The slot antenna plate 37 is formed in a thin disk shape. The plurality of slot holes 40, as illustrated in FIG. 3, are formed so that two slot holes 40 are paired to be perpendicular to each other and apart from each other at a predetermined interval, and pairs of the slot holes 40 are formed in the circumferential direction in a predetermined interval. Also, the plurality of pairs of slot holes 40 are formed at a predetermined interval in the radial direction.

The microwave generated by the microwave generator 35 is propagated through the coaxial waveguide 56. The microwave radially spreads from an area interposed between the slot antenna plate 37 and a cooling jacket 52 which has a circulation path 60 for circulating a refrigerant therein to control the temperature of, for example, the dielectric member 38 to the outside in the radial direction, and then is radiated from the plurality of slot holes 40 formed in the slot antenna plate 37 to the dielectric window 36. The microwave, which has transmitted through the dielectric window 36, generates an electric field just below the dielectric window 36, and generates the plasma within the processing chamber 32.

When the microwave plasma is generated in the plasma doping apparatus 31, a so-called plasma generating area with a relatively high electron temperature of the plasma is formed just below the bottom surface 48 of the dielectric window 36, specifically, at an area positioned about several centimeters below the bottom surface 48 of the dielectric window 36. Then, at an area positioned perpendicularly below the plasma generating area, a so-called plasma diffusion area is formed in which the plasma generated in the plasma generating area is diffused. The plasma diffusion area has a relatively low electron temperature of the plasma, in which plasma processing, that is, plasma doping is performed. Also, when the microwave plasma is generated in the plasma doping apparatus 31, the electron density of the plasma becomes relatively high. Then, at the time of plasma doping, so-called plasma damage to the substrate W is not caused. Also, since the electron density of the plasma is high, efficient plasma doping, specifically, for example, shortening of a time required for doping may be achieved.

Hereinafter, a method of performing plasma doping on a substrate W by using such a plasma doping apparatus will be described. FIG. 4 is a flow chart illustrating a schematic process of the plasma doping method according to an exemplary embodiment of the present disclosure.

Referring to FIG. 4, first, the substrate W is carried into the processing chamber 32 ((A) in FIG. 4), and held on the holding unit 34. Then, a doping gas is supplied into the processing chamber 32, thereby performing first plasma processing ((B) in FIG. 4). In this case, the control unit 28 controls the pressure control mechanism so as to set the pressure within the processing chamber 32 to a first pressure, for example, a pressure of 5 mTorr or more and less than 100 mTorr. Also, the control unit 28 controls the bias power supply mechanism so as to set the bias power to be supplied to a first bias power, for example, ranging from 750 W to 1100 W.

When the first plasma processing is completed with the elapse of a predetermined time, a second plasma processing is performed. That is, subsequently, a doping gas is supplied into the processing chamber 32, thereby performing the second plasma processing ((C) in FIG. 4). In this case, the control unit 28 controls the pressure control mechanism so as to set the pressure within the processing chamber 32 to a second pressure which is higher than the first pressure, for example, a pressure ranging from 100 mTorr to 250 mTorr. Also, the control unit 28 controls the bias power supply mechanism so as to set the bias power to be supplied to a second bias power which is lower than the first bias power, for example, 450 W or more and less than 750 W. When the second plasma processing is completed with the elapse of a predetermined time, the substrate W is removed from the holding unit 34 and carried out to the outside of the processing chamber 32 ((D) in FIG. 4).

In this manner, the plasma doping is performed on the substrate W. That is, the plasma doping apparatus 31 according to an exemplary embodiment of the present disclosure is configured to implant a dopant into the substrate W, thereby performing doping. The plasma doping apparatus includes: the processing chamber 32 configured to implant the dopant into the substrate W therein; the gas supply unit 33 configured to supply the doping gas or the inert gas for plasma excitation into the processing chamber 32; the holding unit 34 which is disposed within the processing chamber 32 and holds the substrate W thereon; the plasma generating mechanism 39 configured to generate plasma within the processing chamber 32 by using microwave; the pressure control mechanism configured to control a pressure within the processing chamber 32; the bias power supply mechanism configured to supply an AC bias power to the holding unit 34; and the control unit 28 configured to control the plasma doping apparatus 31. Here, the control unit 28 controls the pressure control mechanism so as to set the pressure within the processing chamber 32 to the first pressure, controls the bias power supply mechanism so as to set the bias power to be supplied to the holding unit 34 to the first bias power, and performs the first plasma processing on the substrate W by the plasma generated by the plasma generating mechanism 39. After the first plasma processing, the control unit 28 controls the pressure control mechanism so as to set the pressure within the processing chamber 32 to the second pressure which is higher than the first pressure, controls the bias power supply mechanism so as to set the bias power to be supplied to the holding unit 34 to the second bias power which is lower than the first bias power, and performs the second plasma processing on the substrate W by the plasma generated by the plasma generating mechanism 39.

Also, in the plasma doping method according to an exemplary embodiment of the present disclosure, the dopant is implanted into the substrate W, thereby performing doping. The plasma doping method includes: the first plasma process in which the substrate W is held on the holding unit 34 disposed within the processing chamber 32, the pressure within the processing chamber 32 is controlled to be the first pressure, the bias power to be supplied to the holding unit 34 is controlled to be the first bias power, and the plasma is generated within the processing chamber 32 by using the microwave, thereby performing plasma processing on the substrate W; and the second plasma process in which after the first plasma process, the pressure within the processing chamber 32 is controlled to be the second pressure which is higher than the first pressure, and the bias power to be supplied to the holding unit 34 is controlled to be the second bias power which is lower than the first bias power, thereby performing plasma processing on the substrate W.

Also, in the method of manufacturing a semiconductor device according to an exemplary embodiment of the present disclosure, the semiconductor device is manufactured by implanting the dopant into the substrate W. The method includes: the first plasma process in which the substrate W is held on the holding unit 34 disposed within the processing chamber 32, the pressure within the processing chamber 32 is controlled to be the first pressure, the bias power to be supplied to the holding unit 34 is controlled to be the first bias power, and the plasma is generated within the processing chamber 32 by using the microwave, thereby performing plasma processing on the substrate W; and the second plasma process in which after the first plasma process, the pressure within the processing chamber 32 is controlled to be the second pressure which is higher than the first pressure, and the bias power to be supplied to the holding unit 34 is controlled to be the second bias power which is lower than the first bias power, thereby performing plasma processing on the substrate W.

In such a configuration, it is possible to perform plasma doping which does not cause a significant change in the shape after doping as compared to that before the doping, and has a good conformality. Also, in the following cleaning process, the dopant implanted by doping is hardly desorbed.

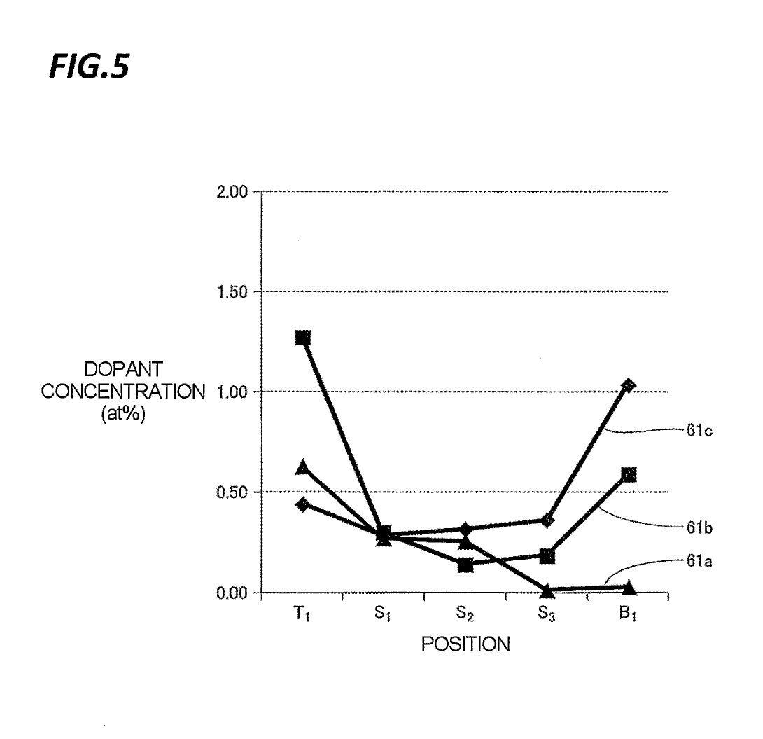

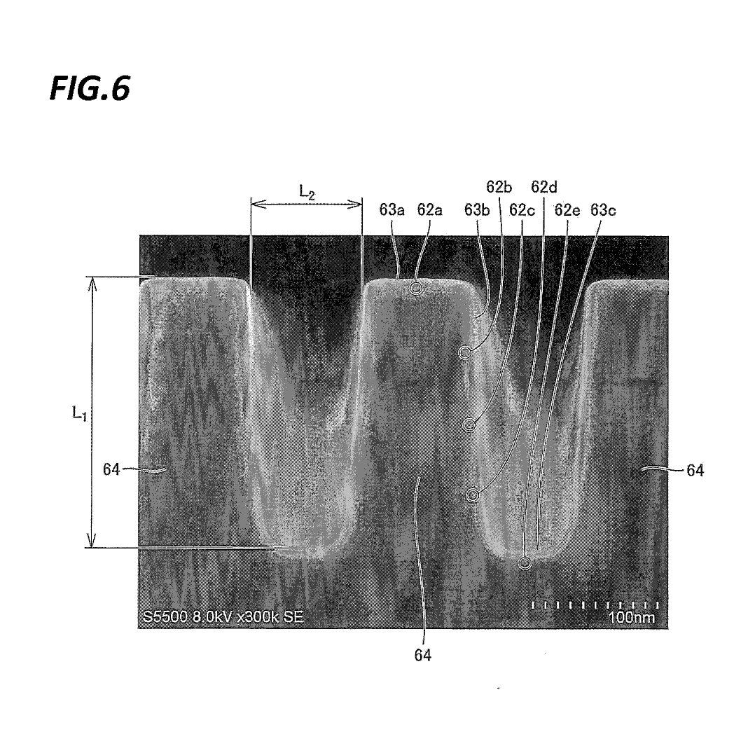

This will be described. FIG. 5 is a graph illustrating dopant concentrations at respective measurement positions of a FinFET-type semiconductor device when doping is performed through various methods. FIG. 6 is an enlarged electron microscopic photograph illustrating a part of a section of the FinFET-type semiconductor device. The respective measurement positions in FIG. 5 are illustrated in FIG. 6. In the broken-line graph in FIG. 5, the horizontal axis indicates measurement positions illustrated in FIG. 6, and the vertical axis indicates dopant concentrations (at(atomic)%). In the respective measurement positions, the depths from the nearest surface are considered to be almost the same. The dopant concentrations illustrated in FIG. 5 indicate values when As (arsenic) is implanted into a silicon substrate.

Hereinafter, the measured concentration of the dopant will be simply described. For the concentration of the doped As dopant, quantitative analysis by SEM (Scanning Electron Microscope)-EDX (Energy Dispersive X-ray Spectroscopy) was performed. This is a method for detecting a characteristic X-ray generated by electron beam irradiation and performing elemental analysis or compositional analysis through energy spectrometry. As a measuring instrument, an)(FLASH silicon drift detector QUANTAX (BRUKER) was used. The measurement was performed under the conditions of acceleration voltage of 8 kV, magnification of 500 k, and irradiation time of 10 seconds. Then, for each sample of the FinFET structure illustrated in FIG. 6, at a measurement point within the area of each measurement position in FIG. 6, quantitative analysis was performed through point analysis. In the quantitative analysis, weight % of each element such as silicon (Si), oxygen (O), or arsenic (As) was firstly obtained, and based on the atomic weight of each element, the concentration (at(atomic:)%) of the dopant was calculated.

The black triangles and the solid line 61a in FIG. 5 indicate the case where doping is performed using a conventional ion implantation device. The black squares and the solid line 61b in FIG. 5 indicate the case where doping is performed without a change of a pressure and a bias power from the beginning to the end during plasma processing. The black lozenges and the solid line 61c in FIG. 5 indicate the case where doping is performed by the plasma doping method and the plasma doping apparatus according to an exemplary embodiment of the present disclosure.

Hereinafter, in the case indicated by the black lozenges and the solid line 61c in FIG. 5, conditions for performing the doping will be described. In the first plasma process, as a doping gas, AsH₃ gas was used, and as a dilution gas, He gas was used. In this case, the gas flow rate ratio was set to AsH₃/He=28 sccm/972 sccm. As a first pressure, 50 mTorr was employed, and as a first bias power, 750 W was employed. Also, the processing time for the first plasma processing was set to 40 seconds. Also, in the second plasma process, as a doping gas and a dilution gas, AsH₃ gas and He gas were used, respectively, in the same manner as in the first plasma process. In this case, the gas flow rate ratio was set to AsH₃/He=98 sccm/902 sccm. As a second pressure, 150 mTorr was employed, and as a second bias power, 450 W was employed. Also, the processing time for the second plasma processing was set to 80 seconds. In all the plasma processes, a microwave power was set to 3 kW. Also, as a substrate W, a silicon substrate with a diameter of 300 mm was used. Also, in the case indicated by the black squares and the solid line 61b in FIG. 5, conditions for performing the doping include only the conditions in the second plasma process. Also, in the case indicated by the black triangles and the solid line 61a in FIG. 5, conditions for performing the doping include irradiation of an ion beam (3.5 keV, a dose of 2×10E15(atoms/cm²)) at an angle of 45°.

Also, an area 62a (T₁) in FIG. 6 indicates a measurement position of a top portion 63a of a fin 64. An area 62b (S₁) in FIG. 6 indicates a measurement position close to the top portion 63a in the height direction of the fin 64 at a side portion 63b. An area 62c (S₂) in FIG. 6 indicates a measurement position of an intermediate area between the top portion 63a and a bottom portion 63c in the height direction of the fin 64 at the side portion 63b. An area 62d (S₃) in FIG. 6 indicates a measurement position close to the bottom portion 63c in the height direction of the fin 64 at the side portion 63b. An area 62e (B₁) in FIG. 6 indicates a measurement position of the bottom portion 63c. The area 62b is positioned 150 nm above the bottom portion 63c in the height direction of the fin 64. The area 62c is positioned 100 nm above the bottom portion 63c in the height direction of the fin 64. The area 62d is positioned 50 nm above the bottom portion 63c in the height direction of the fin 64. Also, respective measurement positions are positioned several nanometers inside of the nearest surface. Both the area 62a of the top portion 63a, and the area 62e of the bottom portion 63c are positioned at almost the center of the top portion 63a and the bottom portion 63c in the width direction of the fin 64. Also, the height of the fin 64 indicated by length L₁ in FIG. 6 is about 200 nm, and the width of the fin 64 indicated by length L₂ in FIG. 6 is about 90 nm.

Here, in the FinFET-type semiconductor device including the fin 64, the top portion 63a and the side portion 63b of the fin 64 will become a region that forms a drain or a source afterwards. Thus, it is the ideal doping that makes the dopant concentration uniform at any position of the top portion 63a and the side portion 63b if possible. Unlike the top portion 63a and the side portion 63b of the fin 64, the bottom portion 63c will not become a region that forms a drain or a source afterwards. Accordingly, compared to the uniformity of the top portion 63a and the side portion 63b, a high or low dopant concentration does not have much effect. That is, in connection with the conformality in the FinFET-type semiconductor device including the fin 64, the uniformity in dopant concentration at the top portion 63a and the side portion 63b of the fin 64 is important.

Referring to FIGS. 5 and 6, when the doping is performed in the conventional ion implantation device, the area 62a of the top portion 63a has a highest dopant concentration. In relation to the side portion 63b, the area 62b close to the top portion 63a and the area 62c at the intermediate position have lower dopant concentrations than the area 62a, and the dopant concentrations at the area 62d close to the bottom portion 63c and the area 62e of the bottom portion 63c are almost 0 (zero). That is, it may be appreciated that doping is hardly performed at the area 62d close to the bottom portion 63c and the area 62e of the bottom portion 63c. Such doping is insufficient from the standpoint of conformality.

Also, in connection with such a phenomenon in the ion implantation device, the followings may be considered. In the ion implantation where a dopant is irradiated at a certain degree of angle to a dopant target, irradiated ions may not reach the area 62d close to the bottom portion 63c in the height direction of the fin 64 at the side portion 63b, or the area 62e of the bottom portion 63c since the fin 64 has a substantial height. As a result, the dopant concentration is thought to become almost 0. This tendency becomes conspicuous when a photoresist layer is formed in the step prior to performing doping.

Also, when doping is performed by carrying out a plasma process once using the microwave plasma, the area 62b close to the top portion 63a, the area 62c of the intermediate position, and the area 62d close to the bottom portion 63c, at the side portion 63b, are not significantly varied in the dopant concentration. However, the area 62a of the top portion 63a has a higher dopant concentration than the areas 62b, 62c, and 62d of the side portion 63b. That is, it can be determined that the top portion 63a side is more highly doped than the side portion 63b. Such doping is also not preferred from the standpoint of conformality.

On the other hand, when the doping is performed by the plasma doping method and the plasma doping apparatus according to an exemplary embodiment of the present disclosure, the dopant concentration at the area 62e of the bottom portion 63c is relatively high. However, the area 62a of the top portion 63a, and the areas 62b, 62c, and 62d of the side portion 63b have almost the same dopant concentrations. Such doping allows a good conformality to be achieved.

Also, specific values of the respective dopant concentrations in FIG. 5 are as follows. When the doping is performed by the conventional ion implantation device, as indicated by the black triangles and the solid line 61a in FIGS. 5, T₁=0.63, S₁=0.27, S₂=0.26, S₃=0.02, and B₁=0.03. Also, when the doping is performed by carrying out a plasma process once using the microwave plasma, as indicated by the black squares and the solid line 61b in FIGS. 5, T₁=1.27, S₁=0.30, S₂=0.14, S₃=0.19, and B₁=0.59. Also, when the doping is performed by carrying out a plasma process twice using the microwave plasma, as indicated by the black lozenges and the solid line 61c in FIGS. 5, T₁=0.44, S₁=0.29, S₂=0.32, S₃=0.37, and B₁=1.04. The unit of all the concentrations is at % as described above.

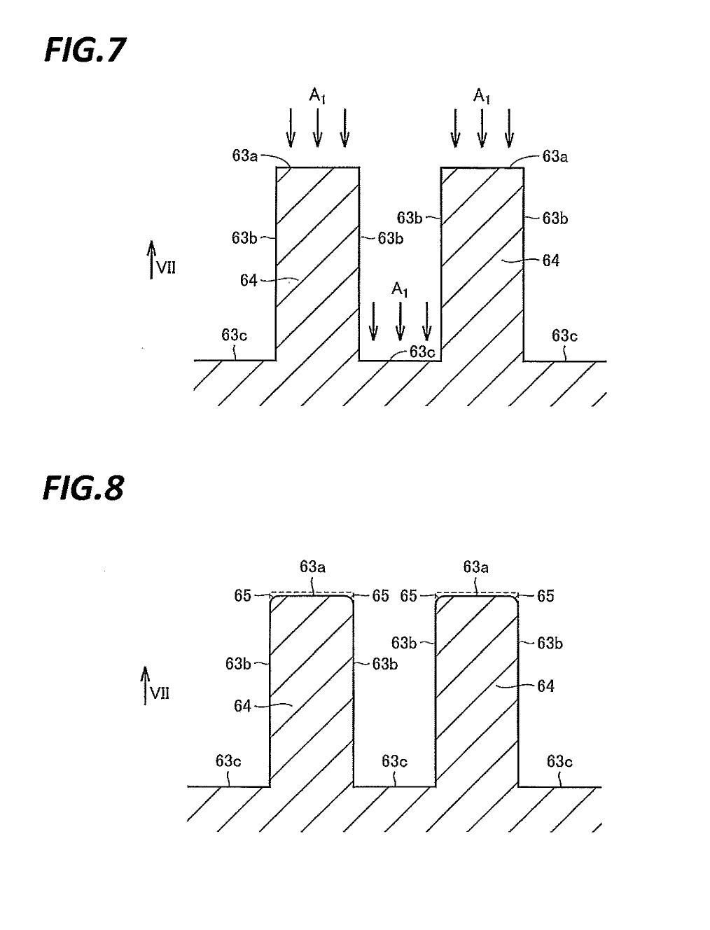

The results will be discussed below. FIGS. 7 and 8 are sectional views schematically illustrating a part of a section of the FinFET-type semiconductor device. The sections illustrated in FIGS. 7 and 8 are those taken along a plane extending in the thickness direction of the substrate W, which correspond to the drawing viewed in the direction of arrow I in FIG. 1, and a part taken as the electron microscopic photograph illustrated in FIG. 6. Also, the protrusion direction of the fins is indicated by arrow VII in FIGS. 1, 7 and 8. FIG. 7 illustrates the case where the first plasma process is performed. FIG. 8 illustrates the case where the second plasma process is performed.

Referring to FIGS. 7 and 8, first, in the first plasma process, the first bias power is supplied to the holding unit. In this case, a relatively high bias power ranging from 750 W to 1100 W is supplied. Also, the pressure within the processing chamber is set to the first pressure. In this case, the pressure is set to a relatively low pressure of 5 mTorr or more and less than 100 mTorr. Then, the dopant supplied into the processing chamber tends to be more directional in the direction perpendicular to the substrate W, as indicated by arrow A₁ in FIG. 7. When the plasma processing is performed in such a state, the top portions 63a exposed at the top side are more highly doped than the side portions 63a by the highly directional dopant and are formed with a thin pre-amorphous layer. The pre-amorphous layer refers to a layer which is placed in a state close to an amorphous state but not an amorphous state, that is, a non-crystalline state. In this case, as indicated by arrow A₁, since the directionality of the dopant from the top to the bottom gets higher, the pre-amorphous layer is hardly formed at the side portions 63b. In this manner, a lot of pre-amorphous layer is formed at the top portions 63a. Also, in this case, it is thought that a lot of pre-amorphous layer is formed at the bottom portions 63c exposed to the top side.

Then, the second plasma process is performed. Here, the second bias power which is lower than the first bias power is supplied to the holding unit. In this case, a relatively low bias power of 450 W or more and less than 750 W is supplied. Also, the pressure within the processing chamber is set to the second pressure which is higher than the first pressure. In this case, the pressure within the processing chamber is set to a relatively high pressure ranging from 100 mTorr to 250 mTorr. In this manner, the directionality becomes low. That is, highly isotropic doping is performed. As a result, the side portions 63b are doped from the surface to an appropriate depth. In this case, the directionality gets lower, and isotropy gets higher. Thus, on the side portions 63b, the doping is equally performed at the areas which are close to either of the top portions 63a and the bottom portions 63c. That is, the depth of the doping and the concentration of the dopant are hardly changed at the areas which are close to either of the top portion 63a and the bottom portion 63c.

Also, the top portions 63a are relatively highly doped in the first plasma process. That is, the top portion is more deeply doped as compared to the side portion 63b.

Here, since the top portions 63a are each formed with a pre-amorphous layer, the portion formed with the pre-amorphous layer is slightly cut in the second plasma process. In this case, the top portions 63a are relatively evenly cut. Also, the external shape of the fins 64 before cut is illustrated by the dotted line in FIG. 8. The pre-amorphous layer is appropriately removed from the top portions 63a which have been deeply doped in the first plasma process, and as a result, each top portion 63a exposes a new surface. By this, the doping depth and the dopant concentration in the side portions 63b become almost the same as the doping depth and the dopant concentration in the top portions 63a, respectively. It is believed that due to such a mechanism, a good conformality may be achieved.

Also, in the bottom portions 63c, since deposition (such as deposition of reaction by-products) occurs at the same time, the dopant concentration becomes slightly higher than those in the top portions 63a and the side portions 63b. However, there is no serious problem in the manufacturing as semiconductor devices as described above.

Also, the corner portions 65 formed by the top portions 63a and the side portions 63b are slightly rounded due to the cutting of the pre-amorphous layer. However, in this change of shape, the corner portions 65 are cut by only several nm, but the side portions 63b are hardly cut. This is a level which does not cause any substantial problem in practical use. That is, the shape is not significantly changed after the doping is performed, as compared to the shape before the doping is performed.

It is believed that the plasma doping using the plasma doping apparatus and the plasma doping method according to an exemplary embodiment of the present disclosure is performed in this manner.

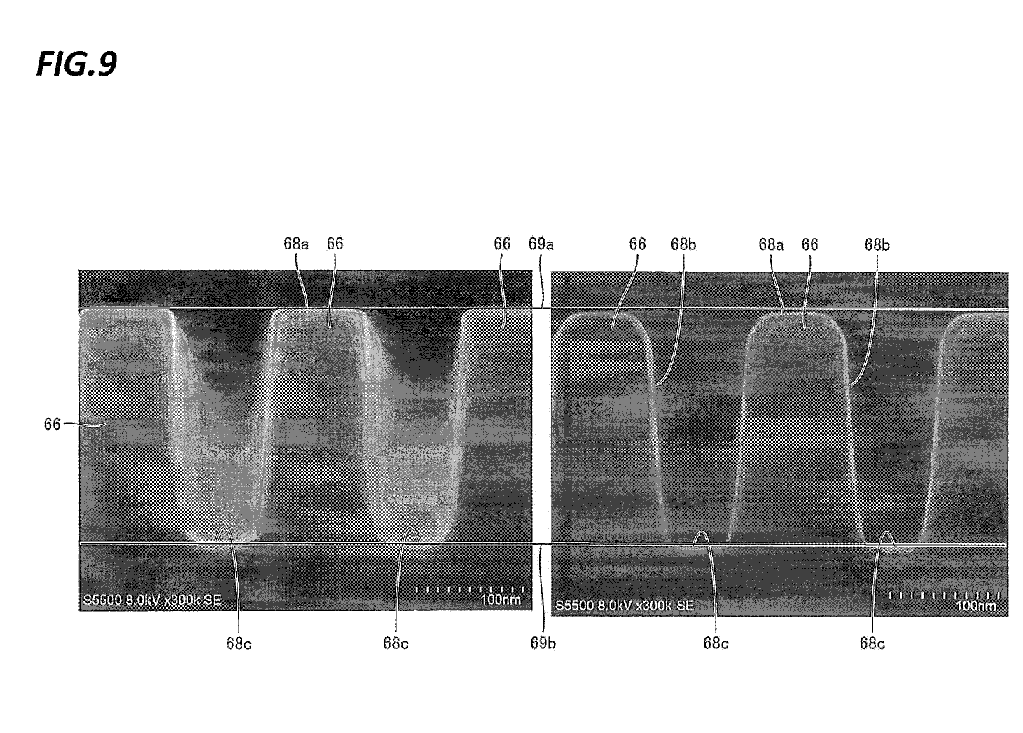

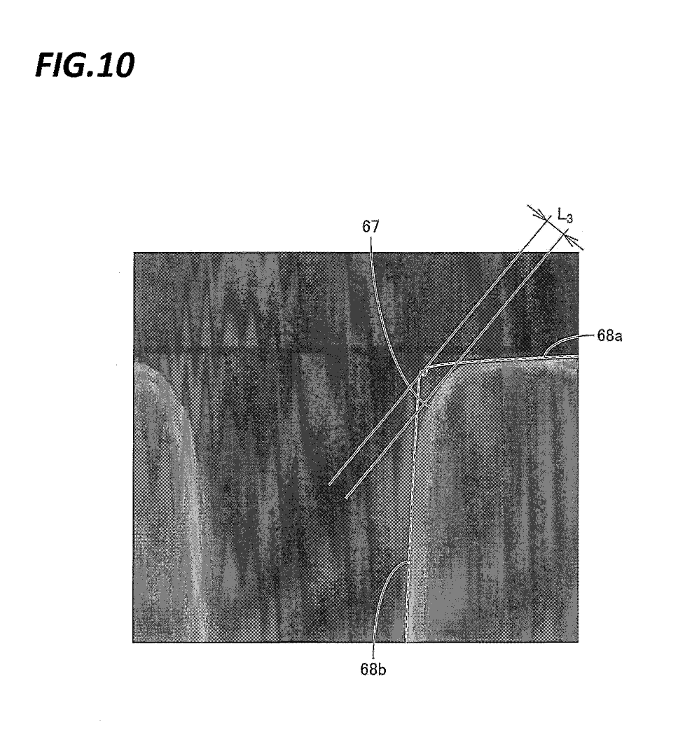

FIGS. 9 and 10 illustrate enlarged electron microscopic photographs illustrating a part of a section of the FinFET-type semiconductor device. The left photograph in FIG. 9 illustrates the case before the doping is performed by the plasma doping method and the plasma doping apparatus according to an exemplary embodiment of the present disclosure. The right photograph in FIG. 9 and FIG. 10 illustrate the cases after the doping is performed by the plasma doping method and the plasma doping apparatus according to an exemplary embodiment of the present disclosure. FIG. 10 is an enlarged view illustrating a part of a top portion 68a and a side portion 68b of a fin 66, including a corner portion 67 in the right photograph in FIG. 9. Also, the left and right photographs in FIG. 9 are connected to each other by a line 69a based on the top portions 68a of the fins 66 before the doping is performed, and a line 69b based on bottom portions 68c. Also, in FIG. 10, the external shape of the corner portion 67 prior to the doping is indicated by the dotted line. Referring to FIGS. 9 and 10, after doping, the positions of the top portions 68a become slightly lower than that before doping. However, the level is only by several nm and does not cause any problem. That is, as compared to the shape before doping, the shape after the doping is not significantly changed. Also, the corner portions 67 are cut to exhibit a rounding of about 4 nm as indicated by length L₃ in FIG. 10, as compared to the original shape, but this level does not cause any problem.

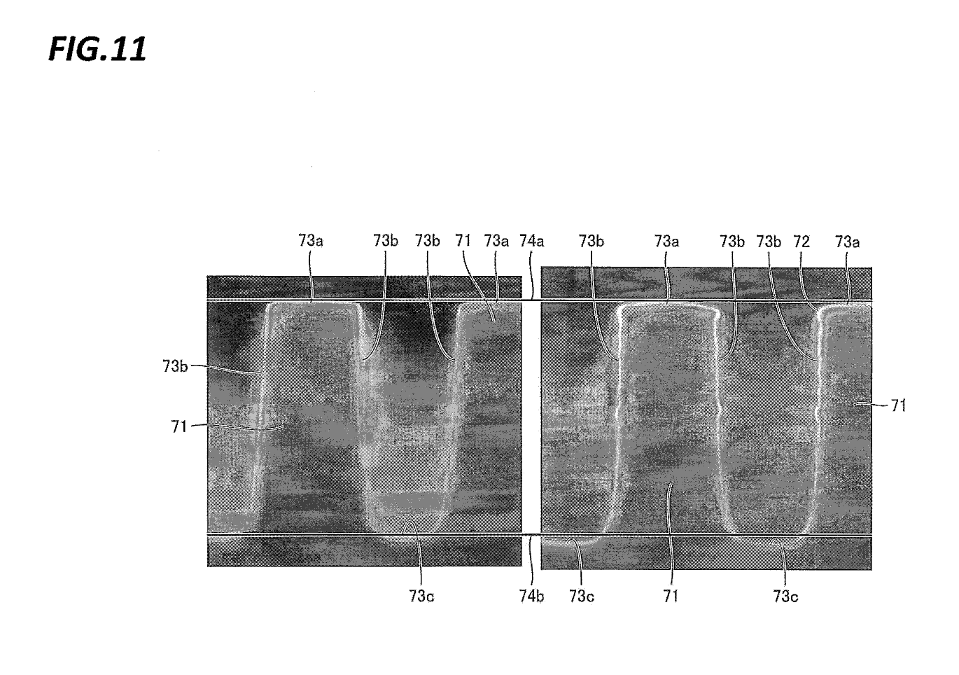

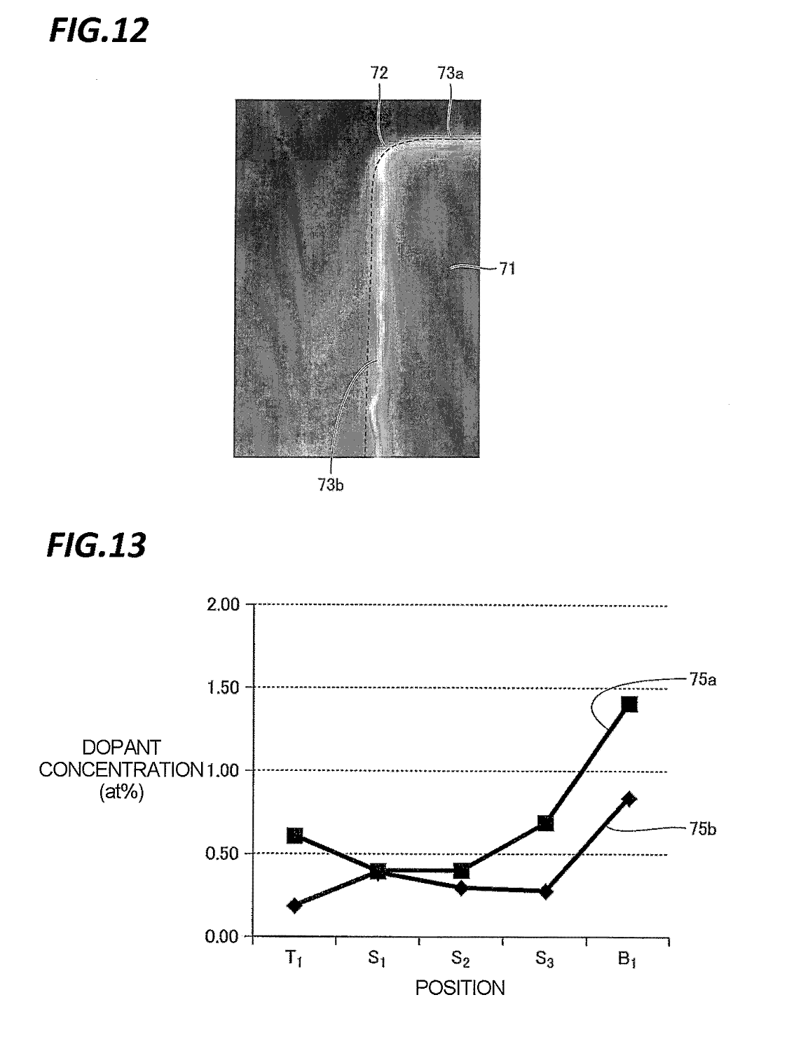

Hereinafter, a case where doping is performed using the conventional ion implantation device will be described. FIGS. 11 and 12 are enlarged electron microscopic photographs illustrating a part of a section of a FinFET-type semiconductor device. The left photograph in FIG. 11 illustrates the case before doping. The right photograph in FIG. 11 and FIG. 12 illustrate the cases after doping. FIG. 12 is an enlarged view illustrating a top portion 73a and a side portion 73b of a fin 71 including a corner portion 72, in the right photograph in FIG. 11. Also, the left and right photographs in FIG. 11 are connected to each other by a line 74a based on the top portions 73a of the fins 71 before doping, and a line 74b based on the bottom portions 73c. Also, in FIG. 12, the external shape of the side portion 73b prior to doping is indicated by the dotted line. Referring to FIGS. 11 and 12, after the doping is performed, the top portion 73a does not show a particular change in height as compared to that before doping. However, it may be observed that the side portion 73b, specifically, the upper side of the side portion 73b close to the top portion 73a is significantly cut. That is, with doping using such an ion implantation device, erosion may be caused greatly. Accordingly, as compared to the shape before doping, the shape after doping is significantly changed. Such a situation is not preferable for the shapes of fins after doping.

Also, for such a phenomenon in the ion implantation device, following things may be considered. That is, in the ion implantation where a dopant is irradiated at a certain degree of angle to a dopant target, the irradiated ions are actively implanted into the areas in the side portions which are close to the top portions in the height direction of the fins since the fins have a substantial height. As a result, it is believed that erosion is caused greatly at the upper sides of the side portions.

Hereinafter, a change in doping concentration before and after a cleaning process will be described. FIG. 13 is a graph illustrating dopant concentrations at respective measurement positions of a FinFET-type semiconductor device before and after cleaning is performed using DHF (diluted hydrofluoric acid) on a substrate which is doped by the plasma doping method and the plasma doping apparatus according to an exemplary embodiment of the present disclosure. In FIG. 13, the black squares and the solid line 75a indicate the case before the cleaning is performed, and the black lozenges and the solid line 75b indicate the case after the cleaning is performed. The vertical axis and the horizontal axis in FIG. 13 are the same as those in FIG. 5. That is, the horizontal axis indicates measurement positions illustrated in FIG. 6, and the vertical axis indicates dopant concentrations (at %). Also, the dopant concentrations illustrated in FIG. 13 indicate those when As (arsenic) is implanted into the silicon substrate. For the cleaning processing using DHF (diluted hydrofluoric acid), immersion is performed in 0.5 weight % of DHF for 20 seconds.

Referring to FIG. 13, except that the dopant concentrations in the area 62b (S₁) are almost the same before and after cleaning, the dopant concentrations are slightly reduced at the respective measurement positions after the cleaning as compared to before cleaning. That is, since the dopant concentrations were not significantly reduced at all the positions, it is understood that even after cleaning, the doped atoms are hardly desorbed. Thus, so-called doping loss may be suppressed. Also, specific values of the respective dopant concentrations in FIG. 13 are as follows. In the case before cleaning, as indicated by the black squares and the solid line 75a in FIGS. 13, T₁=0.61, S₁=0.40, S₂=0.41, S₃=0.69, and B₁=1.41. Also, in the case after cleaning, as indicated by the black lozenges and the solid line 75b in FIGS. 13, T₁=0.19, S₁=0.39, S₂=0.30, S₃=0.28, and B₁=0.84. Meanwhile, the example illustrated in FIG. 13 is obtained by a newly performed experiment, which shows slightly different values from the case where doping is performed by the plasma doping method and the plasma doping apparatus according to an exemplary embodiment of the present disclosure, as indicated by the black lozenges and the solid line 61 c in FIG. 5.

As described above, according to such a configuration, plasma doping may be performed without causing a significant change in shape after doping as compared to that before doping while achieving a good conformality. Also, in the subsequent cleaning processes, the dopant implanted through the doping is hardly desorbed.

Here, the first pressure in the first plasma process may be a value which is not in the range of 5 mTorr or more and less than 100 mTorr. As the first pressure, a pressure ranging from 40 mTorr to 75 mTorr is preferably selected. Also, the first bias power in the first plasma process may be a value which does not range from 750 W to 1100 W. Also, since the area of the substrate W with a diameter of 300 mm (30 cm) is about 706.5 cm², a load of 1.06 W/cm² is applied to the substrate W when the bias power is 750 W and a load of 1.56 W/cm² is applied to the substrate W when the bias power is 1100 W.

Also, the second pressure in the second plasma process may be a value which does not range from 100 mTorr to 250 mTorr. As the second pressure, a pressure ranging from 150 mTorr to 250 mTorr is preferably selected. Also, the second bias power in the second plasma process may be a value which is not in the range of 450 W or more and less than 750 W. As the second bias power, a value of 200 W or more is preferably selected. Also, a load of 0.64 W/cm² is applied to the substrate W when the bias power is 450 W, and a load of 0.28 W/cm² is applied to the substrate W when the bias power is 200 W.

In the above described exemplary embodiment, AsH₃ gas is used as the doping gas, but the present disclosure is not limited thereto. In the configuration of the present disclosure, the doping gas may include at least one selected from the group consisting of B₂H₆, PH₃, AsH₃, GeH₄, CH₄, NH₃, NF₃, N₂, HF, and SiH₄.

Also, in the above described exemplary embodiment, He is used as the inert gas for plasma excitation, but the present disclosure is not limited thereto. In the configuration of the present disclosure, the inert gas may include at least one selected from the group consisting of He, Ne, Ar, Kr, and Xe.

Also, in the above described exemplary embodiment, a silicon substrate is used as the substrate, but the present disclosure is not limited thereto. For example, the present disclosure may be sufficiently applied even when the doping is performed on an interlayer film.

Also, in the above described exemplary embodiment, the plasma doping apparatus is configured to include a dielectric member, but the present disclosure is not limited thereto. Another configuration which does not include the dielectric member may be employed.

Also, in the above described exemplary embodiment, the plasma processing is performed by microwave through a radial line slot antenna that employs the slot antenna plate, but the present disclosure is not limited thereto. A plasma doping apparatus which has a comb-shaped antenna part and generates plasma by microwave or a plasma doping apparatus which generates plasma by radiating microwave from a slot may be used.

Exemplary embodiments of the present disclosure have been described with reference to drawings, but the present disclosure is not limited to the above described exemplary embodiments. The described exemplary embodiments may be variously modified or changed within the same or equivalent scope of the present disclosure.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma doping apparatus comprising:
a processing chamber configured to accommodate a substrate to be processed so that the substrate is implanted with a dopant;
a gas supply unit configured to supply a doping gas and an inert gas for plasma excitation into the processing chamber;
a holding unit disposed within the processing chamber and configured to hold the substrate thereon;
a plasma generating mechanism configured to generate a plasma within the processing chamber by using a microwave;
a pressure control mechanism configured to control a pressure within the processing chamber;
a bias power supply mechanism configured to supply an AC bias power to the holding unit; and
a control unit configured to control the plasma doping apparatus,
wherein the control unit controls the pressure control mechanism so as to set the pressure within the processing chamber to be a first pressure, and controls the bias power supply mechanism so as to set the bias power to be supplied to the holding unit to be a first bias power, so that a first plasma processing is performed on the substrate by the plasma generated by the plasma generating mechanism, and after the first plasma processing, the control unit controls the pressure control mechanism so as to set the pressure within the processing chamber to be a second pressure which is higher than the first pressure, and controls the bias power supply mechanism so as to set the bias power to be supplied to the holding unit to be a second bias power which is lower than the first bias power, so that a second plasma processing is performed on the substrate by the plasma generated by the plasma generating mechanism.

2. The plasma doping apparatus of claim 1, wherein the plasma generating mechanism includes:
a microwave generator configured to generate a microwave for plasma excitation;
a dielectric window configured to transmit the microwave generated by the microwave generator into the processing chamber, and
a slot antenna plate formed with a plurality of slot holes and configured to radiate the microwave to the dielectric window.

3. The plasma doping apparatus of claim 2, wherein the plasma generated by the plasma generating mechanism is generated through a radial line slot antenna.

4. A plasma doping method, comprising:
conducting a first plasma process wherein a substrate to be processed is held on a holding unit disposed within a processing chamber, a pressure within the processing chamber is controlled to be a first pressure, a bias power to be supplied to the holding unit is controlled to be a first bias power, and a plasma is generated within the processing chamber by using a microwave while introducing a doping gas to the processing chamber, thereby implanting a dopant to the substrate; and
after the first plasma process, conducting a second plasma process wherein the pressure within the processing chamber is controlled to be a second pressure higher than the first pressure, the bias power to be supplied to the holding unit is controlled to be a second bias power lower than the first bias power, and the plasma is generated within the processing chamber by using a microwave while introducing the doping gas to the processing chamber, thereby implanting the dopant to the substrate.

5. The plasma doping method of claim 4, wherein the second plasma process is performed in a state where the second pressure is controlled to be 100 mTorr or more and 250 mTorr or less.

6. The plasma doping method of claim 4, wherein the first plasma process is performed in a state where the first pressure is controlled to be 5 mTorr or more and less than 100 mTorr.

7. The plasma doping method of claim 4, wherein the second plasma process is performed in a state where the second bias power is controlled to be 450 W or more and less than 750 W.

8. The plasma doping method of claim 4, wherein the first plasma process is performed in a state where the first bias power is controlled to be 750 W or more and 1100 W or less.

9. The plasma doping method of claim 4, wherein the plasma generated by using the microwave is generated through a radial line slot antenna.

10. A method of manufacturing a semiconductor device, comprising
conducting a first plasma process wherein a substrate to be processed is held on a holding unit disposed within a processing chamber, a pressure within the processing chamber is controlled to be a first pressure, a bias power to be supplied to the holding unit is controlled to be a first bias power, and a plasma is generated within the processing chamber by using a microwave while introducing a doping gas to the processing chamber, thereby implanting a dopant to the substrate; and
after the first plasma process, conducting a second plasma process wherein the pressure within the processing chamber is controlled to be a second pressure higher than the first pressure, the bias power to be supplied to the holding unit is controlled to be a second bias power lower than the first bias power, and the plasma is generated within the processing chamber by using a microwave while introducing the doping gas to the processing chamber, thereby implanting the dopant to the substrate.

11. The method of claim 10, wherein the second plasma process is performed in a state where the second pressure is controlled to be 100 mTorr or more and 250 mTorr or less.

12. The method of claim 10, wherein the first plasma process is performed in a state where the first pressure is controlled to be 5 mTorr or more and less than 100 mTorr.

13. The method of claim 10, wherein the second plasma process is performed in a state where the second bias power is controlled to be 450 W or more and less than 750 W.

14. The method of claim 10, wherein the first plasma process is performed in a state where the first bias power is controlled to be 750 W or more and 1100 W or less.

15. The method of claim 10, wherein the plasma generated by using the microwave is generated through a radial line slot antenna.
